(19) United States
(12) Patent Application Publication
(10) Pub. No.: US 2026/0119773 A1
(43) Pub. Date: Apr. 30, 2026

(54) THREE-BEND PATTERN ROUTING METHOD

(71) Applicant: INSTITUTE OF ELECTRONIC DESIGN AUTOMATION, PEKING UNIVERSITY, WUXI, Wuxi, Jiangsu (CN)

(72) Inventors: Yibo LIN, Wuxi (CN); Chunyuan ZHAO, Wuxi (CN); Zuodong ZHANG, Wuxi (CN)

(21) Appl. No.: 19/164,487

(22) PCT Filed: Dec. 31, 2024
(86) PCT No.: PCT/CN2024/144058

§ 371 Date: Sep. 11, 2025

(30) Foreign Application Priority Data
Jul. 5, 2024 (CN) 202410898450.0

(51) Int. Cl. G06F 30/394

(52) U.S. Cl. CPC G06F 30/394

(57) ABSTRACT

A three-bend pattern routing method includes preprocessing a to-be-solved region to obtain a minimum of continuous segments corresponding to each to-be-solved net in the to-be-solved region; constructing a data structure and calculating a minimum cost of three-bend pattern routing schemes; and finally querying, based on the data structure, a minimum of the segments corresponding to each net, where querying can be performed in parallel.

This application claims priority to Chinese Patent Application No. 202410898450.0 filed with the China National Intellectual Property Administration (CNIPA) on Jul. 5, 2024, the disclosure of which is incorporated herein by reference in its entirety.

### TECHNICAL FIELD

The present application relates to the field of integrated circuit automated design, for example, to a three-bend pattern routing method.

### BACKGROUND

Global routing is a critical stage in physical design, during which a program generates a coarse-grained routing result. The coarse-grained routing result serves to guide subsequent detailed routing steps by identifying target regions, thereby reducing the time cost of detailed routing and improving its overall quality.

The time required for global routing is significantly shorter than that for detailed routing. As such, global routing is frequently employed in the early stages of physical design to rapidly assess design quality and enable timely adjustments to suboptimal or problematic regions.

With the increasing scale of modern circuits, global routing may take several hours or even days to complete. Enhancing the speed of global routing without compromising its quality has thus become a key technical challenge in the field of design automation.

Conventional global routing approaches often utilize net-level parallelism. However, due to large disparities in the scale of individual nets, conventional global routing approaches frequently suffer from load imbalance issues, which hinder the efficiency of multi-threaded processing. Moreover, existing research into GPU (Graphics Processing Unit) algorithms remains limited, and there is a growing need for optimized GPU algorithms to fully harness the computational power of the GPUs.

### SUMMARY

The present application provides a three-bend routing method. The method, although increasing the total computational load, significantly reduces the impact of load imbalance and is more suitable for computing devices with numerous parallel processing units, such as GPUs, thereby greatly improving computational efficiency and reducing the time required for computation.

An embodiment of the present application provides a three-bend pattern routing method. The three-bend pattern routing method includes: calculating edge weights in both a row-direction and a column-direction corresponding to each of points in a to-be-solved region, and calculating a prefix sum of the edge weights corresponding to each of the points; calculating costs of three-bend pattern routing schemes corresponding to each of the points using the prefix sum corresponding to each of the points; constructing a data structure, and calculating, in parallel, a minimum cost of the three-bend pattern routing schemes within a specified segment corresponding to algorithms, based on the costs of the three-bend pattern routing schemes corresponding to each of the points; and executing the algorithms in parallel on the data structure based on the minimum cost of the three-bend pattern routing schemes, calculating a minimum of segments corresponding to each of nets, and routing each of the nets using the minimum of the segments corresponding to each of the nets.

In an embodiment, before calculating the edge weights in both the row-direction and the column-direction corresponding to each of the points in the to-be-solved region, the three-bend pattern routing method further includes preprocessing the to-be-solved region.

In an embodiment, preprocessing the to-be-solved region includes: labeling one or more regions corresponding to each of to-be-solved nets; and mapping a region in a two-dimensional space among the one or more regions corresponding to each of the to-be-solved nets to a one-dimensional space, to obtain a one-dimensional sequence, where each of the to-be-solved nets corresponds to continuous segments in the one-dimensional sequence, and a length of a segment among the continuous segments is equal to an area of the one or more regions corresponding to each of the to-be-solved nets.

In an embodiment, calculating the prefix sum of all the edge weights corresponding to each of the points and calculating the costs of three-bend pattern routing schemes corresponding to each of the points using the prefix sum corresponding to each of the points includes calculating the prefix sum of all the edge weights corresponding to each of the points based on the one-dimensional sequence, and calculating the minimum cost of the three-bend pattern routing schemes corresponding to each of the points using the prefix sum.

Executing the algorithms in parallel on the data structure based on the minimum cost of the three-bend pattern routing schemes, and calculating the minimum of the segments corresponding to each of the nets includes calculating an answer for each of the to-be-solved nets based on the minimum cost of the three-bend pattern routing schemes corresponding to each of the points, where the answer for each of the to-be-solved nets is the minimum of the segments corresponding to each of the to-be-solved nets, and the segments corresponding to each of the to-be-solved nets are continuous segments.

In an embodiment, calculating the edge weights in both the row-direction and the column-direction corresponding to each of the points in the to-be-solved region, and calculating the prefix sum of all the edge weights corresponding to each of the points includes: for the to-be-solved nets, in an arbitrary order of the to-be-solved nets, numbering, in a row-direction arrangement order and a column-direction arrangement order, each of points that may serve as mid points of the three-bend pattern routing schemes in the one or more regions corresponding to each of the to-be-solved nets, to obtain a row-direction numbering sequence and a column-direction numbering sequence; and calculating in parallel, based on the row-direction numbering sequence and the column-direction numbering sequence respectively, the prefix sum of the edge weights in both the row-direction and the column-direction corresponding to each of the points.

In an embodiment, constructing the data structure, and calculating, in parallel, the minimum cost of the three-bend pattern routing schemes within the specified segment corresponding to the algorithms, based on the costs of the three-bend pattern routing schemes corresponding to each of the points includes calculating one or more special segments, and calculating a minimum cost of the three-bend pattern routing schemes within a specified special segment of the one or more special segments.

In an embodiment, constructing the data structure includes denoting that d(i, j) is a segment with i as a left endpoint and a length of 2^{j} to obtain a minimum of left-closed, right-open segments from i to i+2^{j}; and determining one or more segments with i being a multiple of 2^{j} as the one or more special segments, and calculating a minimum cost of the three-bend pattern routing schemes for each of the one or more special segments.

In an embodiment, the three-bend pattern routing method also includes querying an answer, where querying the answer includes: querying the answer comprises: each time, finding one or more longest special segments that have a same left endpoint as a to-be-queried segment and are contained within the to-be-queried segment, incorporating a minimum of the one or more longest special segments into the answer to obtain an incorporated answer, and determining whether to end the querying or continue querying based on the incorporated answer until a final answer is obtained.

In an embodiment, in a case where no dependency or contention relationship exists during a querying process for each of the to-be-solved nets, parallel querying is performed.

### BRIEF DESCRIPTION OF DRAWINGS

FIG. 1 is a schematic diagram of routing for a three-bend pattern routing method according to an embodiment of the present application.

FIG. 2 is a flowchart of a three-bend pattern routing method according to an embodiment of the present application.

FIG. 3 is a schematic diagram of data structure construction and answer querying for a three-bend pattern routing method according to an embodiment of the present application.

### DETAILED DESCRIPTION

The present application will be described with reference to the drawings and embodiments. It is to be understood that the embodiments described herein are intended to explain and not to limit the present application.

In the following description, for purposes of explanation rather than limitation, specific details such as particular internal procedures and techniques are provided for a thorough understanding of the embodiments of the present application. However, it is apparent to those skilled in the art that the present application may be implemented in other embodiments without these specific details. In other cases, descriptions of well-known systems, devices, circuits, and methods are omitted to avoid unnecessary details that may obscure the description of the present application.

Embodiments of the present application provide a three-bend pattern routing method. The three-bend pattern routing method includes the following steps:

Edge weights in both a row-direction and a column-direction corresponding to each of points in a to-be-solved region are calculated, and a prefix sum of the edge weights corresponding to each of the points is calculated.

Costs of three-bend pattern routing schemes corresponding to each of the points are calculated using the prefix sum corresponding to each of the points.

A data structure is constructed, and a minimum cost of the three-bend pattern routing schemes within a specified segment corresponding to algorithms is calculated in parallel based on costs of the three-bend pattern routing schemes corresponding to each of the points.

The algorithms are executed in parallel based on the data structure based on the minimum cost of the three-bend pattern routing schemes, a minimum of segments corresponding to each of nets is calculated, and each of the nets is routed using the minimum of the segments corresponding to each of the nets, that is, to obtain an optimal scheme of three-bend routing.

In preprocessing of the to-be-solved region, one or more regions corresponding to each of to-be-solved nets are labeled, and a region in a two-dimensional space among the one or more regions corresponding to each of the to-be-solved nets is mapped to a one-dimensional space to obtain a one-dimensional sequence, where each of the to-be-solved nets corresponds to continuous segments in the one-dimensional sequence, and a length of a segment among the continuous segments is equal to the area of the one or more regions corresponding to each of the to-be-solved nets. By that the prefix sum of the edge weights is calculated based on the one-dimensional sequence and a cost of an optimal three-bend pattern routing scheme corresponding to each of the points is calculated using the prefix sum, an answer for each of the to-be-solved nets is a minimum of continuous segments corresponding to each of the to-be-solved nets.

Calculating the edge weights in both the row-direction and the column-direction corresponding to each of the points in the to-be-solved region, and calculating the prefix sum of all the edge weights corresponding to each of the points includes the following steps:

For the to-be-solved nets, in an arbitrary order of the to-be-solved nets, each of points that may serve as mid points of the three-bend pattern routing schemes in the one or more regions corresponding to each of the to-be-solved nets is numbered in a row-direction arrangement order and a column-direction arrangement order, to obtain a row-direction numbering sequence and a column-direction numbering sequence.

The prefix sum of the edge weights in both the row-direction and the column-direction corresponding to each of the points is calculated, based on the row-direction numbering sequence and the column-direction numbering sequence respectively, in parallel.

Constructing the data structure, and calculating the minimum cost of the three-bend pattern routing schemes includes calculating one or more special segments, and calculating a minimum cost of the three-bend pattern routing schemes within a specified special segment of the one or more special segments.

Constructing the data structure includes the following steps: denoting that d(i, j) is a segment with i as a left endpoint and a length of 2^{j} to obtain a minimum of left-closed, right-open segments from i to i+2^{j}; determining one or more segments with i being a multiple of 2^{j} as the one or more special segments, and calculating a minimum cost of the three-bend pattern routing schemes for each of the one or more special segments. In a case where no dependency or contention relationship exists during a querying process for each of the to-be-solved nets, parallel querying is performed.

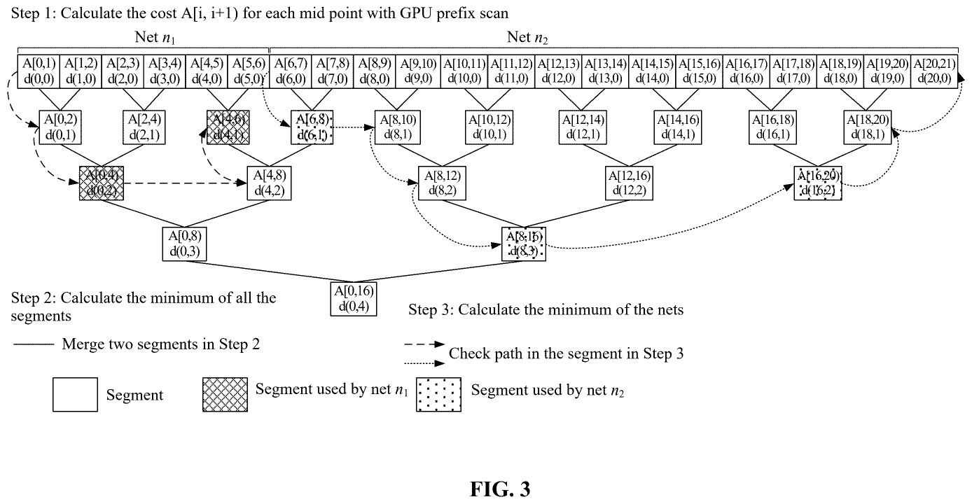

As shown in FIG. 3, the first row represents a minimum of segments corresponding to each point, that is, a minimum of segments with a length of 1, denoted as d(i, 0).

The formula for calculating the minimum of special segments is as follows:

$$d ( i , j ) = min \{ d ( i , j - 1 ) , d ( i + {2}^{j - 1} , j - 1 ) \} .$$

Calculation is performed in ascending order of j, and parallel calculation may be performed when j is the same.

Querying the answer includes the following: each time, finding one or more longest special segments that have a same left endpoint as a to-be-queried segment and are contained within the to-be-queried segment, incorporating a minimum of the one or more longest special segments into the answer to obtain an incorporated answer, and determining whether to end the querying or continue the querying based on the incorporated answer until a final answer is obtained.

Embodiments of the present application provide a three-bend pattern routing method, which is a massively parallel three-bend pattern routing method based on range minimum/maximum query (RMQ). The three-bend pattern routing method according the embodiments of the present application is implemented by preprocessing a to-be-solved region, constructing a data structure, and querying of an answer. In the preprocessing of the to-be-solved region, regions corresponding to all to-be-solved nets are labeled, the regions corresponding to the nets and in a two-dimensional space are mapped to a one-dimensional space to obtain a one-dimensional sequence, and each net corresponds to a continuous segment in the one-dimensional sequence, and the length of the continuous segment is equal to the area of a region corresponding to each of the to-be-solved nets. The prefix sum of the edge weights is calculated based on the one-dimensional sequence, and the minimum cost of the three-bend pattern routing schemes corresponding to each of the points is calculated using the prefix sum. In this case, an answer for a net is a minimum of continuous segments corresponding to the net. In the step of data structure construction, specific segments are determined, and a minimum of the specific segments is calculated using a divide-and-conquer approach. In the step of answer querying, a minimum of segments corresponding to each net is queried on the data structure. The process is as follows:

Preprocessing of the to-be-Solved Region

Edge weights along grid-aligned horizontal and vertical directions corresponding to each point in a to-be-solved region are calculated, and a prefix sum of the edge weights is calculated. Costs of three-bend pattern routing schemes corresponding to each of the points is calculated using the prefix sum.

For the to-be-solved nets, in an arbitrary order of the nets, each of points that may serve as mid points of the three-bend pattern routing schemes in the one or more regions corresponding to each of the to-be-solved nets are numbered in a row-direction arrangement order and a column-direction arrangement order, to obtain a numbering sequence. Each possible mid point corresponding to each net corresponds to a point in the numbering sequence, and all mid points corresponding to a net form a continuous segment in the sequence. On this numbering sequence, the prefix sum of the edge weights of edges in both the row-direction and the column-direction can be calculated in parallel. Using the prefix sum, the costs of the three-bend pattern routing schemes corresponding to each point can be calculated in parallel. An optimal three-bend pattern routing scheme to be determined for each to-be-solved net is a three-bend pattern routing scheme with a minimum cost among all the three-bend pattern routing schemes corresponding to the points within a subsegment of the numbering sequence corresponding to the one or more regions corresponding to each to-be-solved net.

### Data Structure Construction

The criterion for determining a special segment is whether i is a multiple of 2^{j} and whether the segment is a subsegment of the original one-dimensional sequence.

The criterion for ending the querying or continuing the querying is whether there is any special segment that has not been calculated.

For each i that is a multiple of 2^{j}, [i, i+2^{j}) is considered as a special segment, and a minimum of all special segments is calculated (if such a special segment exists). When j≥1, a minimum of segments [i, i+2^{j}) may be calculated from a minimum of smaller segments [i, i+2^{j-1}) and [i+2^{j-1}, i+2^{j}). Minimum of segments with the same j may be calculated in parallel.

### Answer Querying

For each net, querying an answer refers to querying a minimum of segments corresponding to each net. Assuming a segment corresponding to a net is [L, R), querying the answer in the following manner: each time, a largest special segment [L, L+2^{j}) that is a subsegment of [L, R) is found, and a minimum of the special segments is incorporated into the answer. Querying the answer is ended until L+2^{j}=R, or is repeated the above to solve [L+2^{j}, R) when L+2^{j}<R. Querying the answer may be performed for not more than O(log₂(R−L)) times. Moreover, in a case where querying for each net has no dependency relationship or contention relationship, parallel querying is performed.

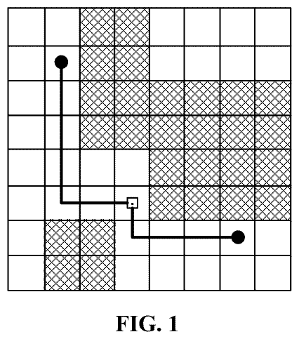

As shown in FIG. 1, a typical three-bend pattern routing scheme is illustrated. Three-bend pattern routing is a category of pattern routing, characterized by restricting a pattern routing scheme from a source to a sink to have at most three bends.

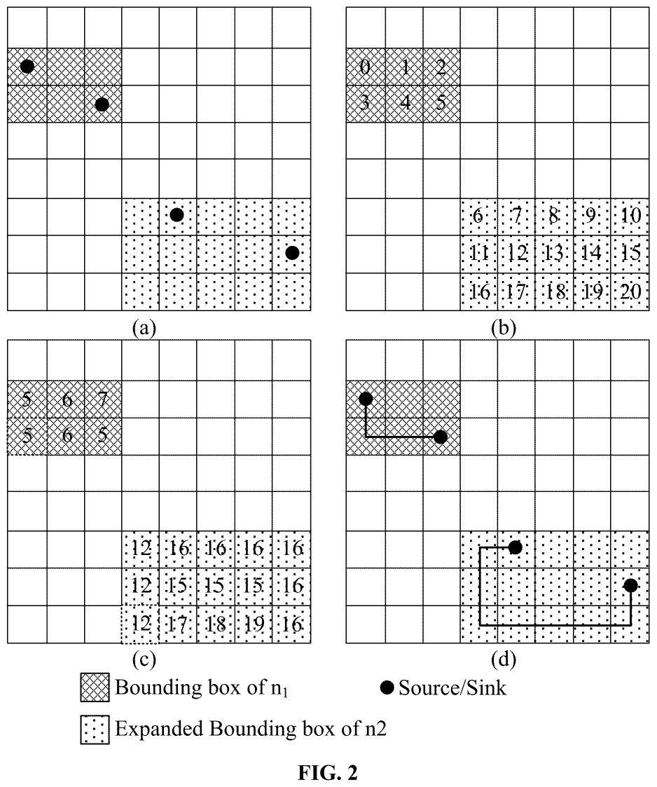

With reference to FIG. 2, for two nets (n1 and n2) in FIG. 2, the two nets are first arranged in order, and points in a to-be-solved region are arranged in order and numbered sequentially. The two nets correspond to numbers 0-5 and 6-20, respectively. A cost of edge weights between each point and its adjacent right point is calculated (such as 0-1 and 1-2). If no point exists to the right, any value may be assumed, which does not affect the algorithm. These edge weights are stored in a one-dimensional sequence (0-20), with position i+1 corresponding to horizontal edge weights between i and a point adjacent to i (such as position 1 stores 0-1, and position 2 stores 1-2). A prefix sum is calculated for this sequence to obtain a prefix sum sequence dₕ of edge weights in the horizontal direction. Similarly, a prefix sum sequence dᵥ of edge weights in the vertical direction is calculated. Edge weights are calculated using any parallel strategy, and the prefix sum algorithm is implemented using any algorithm library. After calculation of dₕ, dᵥ, edge weights for a horizontal or vertical edge segment are directly calculated in a simple manner. For example, for a long horizontal edge from point 6 to point 10 in FIG. 2, the edge weight is the sum of edge weights from 6-7, 7-8, 8-9, and 9-10, that is, dₕ(10)−dₕ(6). For each point, at most four three-bend schemes with this point as a mid turning point are possible. For example, for point 13, the four schemes are (6->8->13->15->20), (6->8->13->18->20), (6->11->13->15->20), and (6->11->13->18->20).

The cost calculation method for 6->8->13->15->20 is as follows:

$${d}_{h} ( 8 ) - {d}_{h} ( 6 ) + {d}_{v} ( 13 ) - {d}_{v} ( 8 ) + {d}_{h} ( 15 ) - {d}_{h} ( 13 ) + {d}_{v} ( 20 ) - {d}_{v} ( 15 ) .$$

The cost calculation method for 6->8->13->18->20 is as follows:

$${d}_{h} ( 8 ) - {d}_{h} ( 6 ) + {d}_{v} ( 13 ) - {d}_{v} ( 8 ) + {d}_{v} ( 18 ) - {d}_{v} ( 13 ) + {d}_{h} ( 20 ) - {d}_{h} ( 18 ) .$$

The cost calculation method for 6->11->13->15->20 is as follows:

$${d}_{v} ( 11 ) - {d}_{v} ( 6 ) + {d}_{h} ( 13 ) - {d}_{h} ( 11 ) + {d}_{h} ( 15 ) - {d}_{h} ( 13 ) + {d}_{v} ( 20 ) - {d}_{v} ( 15 ) .$$

The cost calculation method for 6->11->13->18->20 is as follows:

$${d}_{v} ( 11 ) - {d}_{v} ( 6 ) + {d}_{h} ( 13 ) - {d}_{h} ( 11 ) + {d}_{v} ( 18 ) - {d}_{v} ( 13 ) + {d}_{h} ( 20 ) - {d}_{h} ( 18 ) .$$

The three-bend pattern routing scheme with the minimum cost among the four three-bend pattern routing schemes is determined as the three-bend pattern routing scheme with the minimum cost for this point. By enumerating all three-bend schemes for all points within each net, the algorithm aims to obtain a scheme with the minimum edge weight cost (global pattern routing problems always involve seeking a three-bend pattern routing scheme with the minimum cost under a model; if multiple three-bend pattern routing schemes have the minimum cost, any one is acceptable). For example, in FIG. 2, for the second net, it needs to determine a three-bend pattern routing scheme with the minimum cost among 60 three-bend pattern routing schemes corresponding to 15 mid points (that is, 6-20). For each point, the three-bend pattern routing scheme with the minimum cost among the four three-bend pattern routing schemes corresponding to a point being a mid turning point is determined. In the lower left corner of FIG. 2, the cost of the three-bend pattern routing scheme with the minimum cost for each point is marked.

Next, a data structure is constructed. FIG. 3 illustrates the data structure corresponding to FIG. 2. The first row represents 21 points from 0 to 20. d(i, 0) is a minimum cost of a three-bend pattern routing scheme corresponding to point i. For net 1, the three-bend pattern routing scheme to be found is the one with the minimum cost among the six three-bend pattern routing schemes corresponding to the segment [0,6). For net 2, the three-bend pattern routing scheme to be found is the one with the minimum cost among the 15 three-bend pattern routing schemes corresponding to the segment [6,21). It is denoted that d(i, j) represents a minimum cost of segments [i, i+2^{j}). Only segments with i being a multiple of 2^{j} are calculated for d(i,j). For j≥1 and d(i, j)=min {d(i, j−1), d(i+2^{j-1}, j−1)}, where a segment where i is a multiple of 2^{j} is a special segment, j≥1 and d(i, j)=min {d(i, j−1), d(i+2^{j-1}, j−1)} is the method for calculating a minimum of the special segments. FIG. 3 illustrates all d to be calculated and their data dependencies. It can be noted that segments d(i, j) with the same j can be calculated in parallel. If sufficient computational cores are available, the structure in FIG. 3 may complete all computations within four computation cycles.

Next, an answer is queried through the data structure. For net 1, the longest segment with a calculated minimum cost with 0 as the left endpoint is first incorporated into the answer. From FIG. 3, it can be seen that [0,4) is the longest segment with a calculated minimum cost with 0 as the left endpoint, and d(0,2) is incorporated into the answer. Then, the longest segment with a calculated minimum cost with 4 as the left endpoint is sought. From FIG. 3, it can be seen that [4,6) is the longest segment with a calculated minimum cost with 4 as the left endpoint, and d(4,1) is incorporated into the answer. For net 1, the answer is min (d(0,2), d(4,1). Similarly, for net 2, the answer is min (d(6,1), d(8,3), d(16,2), d(20,0)). It is proven that for any segment of length N, a minimum cost may always be queried on the data structure within O(log₂ N) time. Moreover, it can be noted that querying for different nets may be calculated in parallel.

Compared to a simple method of directly calculating a minimum cost among all schemes in serial, the method of the present application increases the total computational load but reduces the impact of load imbalance, making it more suitable for computing devices with numerous parallel processing units, such as GPUs, thereby greatly improving computational efficiency and reducing the time required for computation.

What is claimed is:

1. A three-bend pattern routing method, comprising:
calculating edge weights in both a row-direction and a column-direction corresponding to each of points in a to-be-solved region, and calculating a prefix sum of the edge weights corresponding to each of the points;
calculating costs of three-bend pattern routing schemes corresponding to each of the points using the prefix sum corresponding to each of the points;
constructing a data structure, and calculating, in parallel, a minimum cost of the three-bend pattern routing schemes within a specified segment corresponding to algorithms, based on the costs of the three-bend pattern routing schemes corresponding to each of the points; and
executing the algorithms in parallel based on the data structure based on the minimum cost of the three-bend pattern routing schemes, calculating a minimum of segments corresponding to each of nets, and routing each of the nets using the minimum of the segments corresponding to each of the nets.

2. The three-bend pattern routing method according to claim 1, wherein before calculating the edge weights in both the row-direction and the column-direction corresponding to each of the points in the to-be-solved region, the three-bend pattern routing method further comprises: preprocessing the to-be-solved region.

3. The three-bend pattern routing method according to claim 2, wherein preprocessing the to-be-solved region comprises:
labeling one or more regions corresponding to each of to-be-solved nets; and
mapping a region in a two-dimensional space among the one or more regions corresponding to each of the to-be-solved nets to a one-dimensional space, to obtain a one-dimensional sequence, wherein each of the to-be-solved nets corresponds to continuous segments in the one-dimensional sequence, and a length of a segment among the continuous segments is equal to an area of the one or more regions corresponding to each of the to-be-solved nets.

4. The three-bend pattern routing method according to claim 3, wherein calculating the prefix sum of all the edge weights corresponding to each of the points and calculating the costs of three-bend pattern routing schemes corresponding to each of the points using the prefix sum corresponding to each of the points comprises:
calculating the prefix sum of all the edge weights corresponding to each of the points based on the one-dimensional sequence, and calculating the minimum cost of the three-bend pattern routing schemes corresponding to each of the points using the prefix sum.

5. The three-bend pattern routing method according to claim 4, wherein executing the algorithms in parallel on the data structure based on the minimum cost of the three-bend pattern routing schemes, and calculating the minimum of the segments corresponding to each of the nets comprises:
calculating an answer for each of the to-be-solved nets based on the minimum cost of the three-bend pattern routing schemes corresponding to each of the points, wherein the answer for each of the to-be-solved nets is a minimum of the segments corresponding to each of the to-be-solved nets, and the segments corresponding to each of the to-be-solved nets are continuous segments.

6. The three-bend pattern routing method according to claim 5, wherein calculating the edge weights in both the row-direction and the column-direction corresponding to each of the points in the to-be-solved region, and calculating the prefix sum of all the edge weights corresponding to each of the points, comprises:
for the to-be-solved nets, in an arbitrary order of the to-be-solved nets, numbering, in a row-direction arrangement order and a column-direction arrangement order, each of points that may serve as mid points of the three-bend pattern routing schemes in the one or more regions corresponding to each of the to-be-solved nets, to obtain a row-direction numbering sequence and a column-direction numbering sequence; and
calculating in parallel, based on the row-direction numbering sequence and the column-direction numbering sequence respectively, the prefix sum of the edge weights in both the row-direction and the column-direction corresponding to each of the points.

7. The three-bend pattern routing method according to claim 1, wherein constructing the data structure, and calculating, in parallel, the minimum cost of the three-bend pattern routing schemes within the specified segment corresponding to the algorithms, based on the costs of the three-bend pattern routing schemes corresponding to each of the points comprises:
calculating one or more special segments, and calculating a minimum cost of the three-bend pattern routing schemes within a specified special segment of the one or more special segments.

8. The three-bend pattern routing method according to claim 7, wherein constructing the data structure comprises:
denoting that d(i, j) is a segment with i as a left endpoint and a length of 2^{j} to obtain a minimum of left-closed, right-open segments from i to i+2^{j}; and
determining one or more segments with i being a multiple of 2^{j} as the one or more special segments, and calculating a minimum cost of the three-bend pattern routing schemes for each of the one or more special segments.

9. The three-bend pattern routing method according to claim 8, further comprising:
querying an answer;
wherein querying the answer comprises: each time, finding one or more longest special segments that have a same left endpoint as a to-be-queried segment and are contained within the to-be-queried segment, incorporating a minimum of the one or more longest special segments into the answer to obtain an incorporated answer, and determining whether to end the querying or continue the querying based on the incorporated answer until a final answer is obtained.

10. The three-bend pattern routing method according to claim 9, wherein in a case where no dependency or contention relationship exists during a querying process for each of the to-be-solved nets, parallel querying is performed.
